(19) United States
(12) Patent Application Publication
(10) Pub. No.: US 2009/0243100 A1
(43) Pub. Date: Oct. 1, 2009

(54) Methods to Form a Three-Dimensionally Curved Pad in a Substrate and Integrated Circuits Incorporating such a Substrate

(76) Inventor: Jotaro Akiyama, Tsukaba Ibaraki (JP)

Correspondence Address: TEXAS INSTRUMENTS INCORPORATED, P O BOX 655474, M/S 3999, DALLAS, TX, 75265, US

(21) Appl. No.: 12/057,056

(22) Filed: Mar. 27, 2008

(51) Int. Cl. H01L 23/488; H01L 21/44

(52) U.S. Cl. 257/738; 438/614; 257/E23.023; 257/E21.476

(57) ABSTRACT

Methods to form a three-dimensionally curved pad in a substrate and integrated circuits incorporating such a substrate are disclosed. An example method to form a three-dimensionally curved pad comprises isotropically etching a portion of a surface of a substrate to form a recess having a radial shape, forming a conductive layer in the recess to form the bonding pad, and placing a conductive element in the pad.

### TECHNICAL FIELD

The present disclosure pertains to integrated circuits and, more particularly, to methods to form a three dimensionally curved, radially shaped pad in a substrate and integrated circuits incorporating such a substrate.

### BACKGROUND

Generally, integrated circuits are placed into a package that is attached to a circuit board of an electronic device or system. To satisfy consumer desire for more portable electronic devices, semiconductor manufacturers seek to incorporate as many devices as possible into the integrated circuit(s) while reducing the amount of circuit board area needed by packaged integrated circuit(s). One method to reduce the circuit board area required by packaged integrated circuits is to stack the integrated circuits on top of each other. Another method to reduce the circuit board area consumed by packaged integrated circuits is to make the packages of the integrated circuits smaller. For example, a typical chip scale package has a surface area of approximately 20% greater than the surface area of the integrated circuit attached thereto.

As a result of the increased integration, packaging processes to manufacture such packaged integrated circuits are more difficult to implement and more prone to electrical and/or reliability failure. Such failures can occur at any process or stage in the assembly of the packaged integrated circuits and/or the corresponding electronic device such as, for example, during solder reflow to attach the packaged integrated circuit to a circuit board.

Conventionally, under bump metallization for solder ball attachment is formed on flat surfaces of substrates. In a known substrate including an metal layer and a polyimide later, conductive plugs placed in holes defined in the polyimide layer. Solder balls are placed in the holes in contact with the conductive plugs. The plugs are planar and improve the solder ball reflow processes by preventing air pockets from being trapped in the holes of the substrate. Such air pockets could electrically isolate the solder balls from the metal layer. The holds formed in the polyimide layer are detents that receive solder, but the polyimide defines the detents does not form a joint with the solder ball.

### BRIEF DESCRIPTION OF THE DRAWINGS

FIG. 1 illustrates a portion of an example substrate having example radially shaped pads.

FIG. 2 illustrates a portion of the example substrate of FIG. 1 attached to an example circuit board.

FIG. 3 is a flowchart of an example process to form the radially shaped pads of FIG. 1.

FIGS. 4A-4H illustrate the example substrate of FIG. 1 at different stages of the example process of FIG. 3.

FIG. 5 illustrates a packaged integrated circuit having the example radially shaped pads formed by the example process of FIG. 3.

FIG. 6 illustrates another example packaged integrated circuit having example radially shaped pads formed by the example process of FIG. 3.

FIG. 7 illustrates yet another example packaged integrated circuit having example radially shaped pads formed by the example process of FIG. 3.

FIG. 8 illustrates an example two-layer packaged integrated circuit having example radially shaped pads formed by the example process of FIG. 3.

FIG. 9 illustrates another example packaged integrated circuit having example radially shaped pads formed by the example process of FIG. 3.

To clarify multiple layers and regions, the thicknesses of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

Methods to form a radially shaped pad in a substrate and integrated circuits incorporating such a substrate are described herein. The dimple-like solder bonding pads(s) described herein improve the stability of solder balls(s) used with the same during the solder ball attachment processes. They also limit deformation of the solder balls during solder reflow to thereby reduce the likelihood of inadvertent short circuits. The methods and apparatus described herein are particularly well suited to forming dimple pads on the inactive (non-circuit) side of a substrate (e.g., silicon, gallium arsenide, etc.). Thus, the methods and apparatus described herein are particularly well suited for forming die-to-die interconnections using through silicon vias and applications employing a silicon interposer between two functional integrated circuits. Although the example methods and apparatus described herein generally relate to substrates of integrated circuits, the disclosure is not limited to such. On the contrary, the teachings of this disclosure may be applied in any device or process which would benefit from radially shaped pads such as, for example, circuit boards.

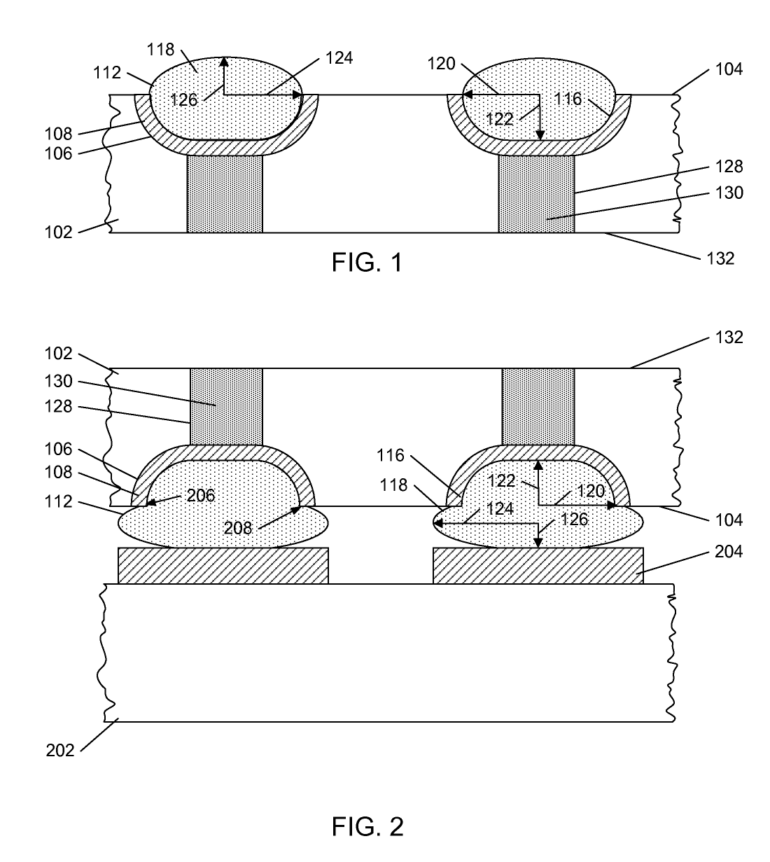

FIG. 1 is an illustration of a portion of an example substrate 102. Generally, a substrate is a material on which an integrated circuit is fabricated by, for example, implanting ions in the substrate to form active devices (e.g., transistors). In such an example, the substrate generally has a first surface (e.g., the active surface) having the active devices adjacent thereto and a second surface opposite the first surface which is attached to a carrier (e.g., a package, a lead frame, etc.). The second surface typically does not include circuitry and/or active devices (although they may), and is thus referred to herein as the inactive surface of the non-circuit side of the substrate 102. The substrate may be implemented by any suitable material (e.g., silicon, silicon germanium, etc.). Of course, the substrate does not necessarily have to contain active devices and can be used to facilitate electrical and mechanical attachment of other integrated circuits (e.g., an interposer, a package substrate, etc.).

In the example of FIG. 1, the second (inactive) surface 104 of the substrate 102 defines one or more three-dimensionally, radially shaped recesses 106. As mentioned above, the inactive surface 104 typically does not include active devices. In other words, the radially shaped recesses 106 of the illustrated example are placed on the non-circuit surface of the substrate 102. In the illustrated example, pads 108 are formed in corresponding ones of the recesses 106. The pads generally conform to their respective recesses and, thus, have radially shaped profiles (e.g., elliptical, circular, etc.). The pads 108 of the illustrated example are bonding pads generally implemented by forming successive layers of metals (e.g., an adhesion layer, a diffusion barrier layer, a solder wettable layer, a protective layer, etc.) and serve the function of allowing solder to be attached to the bonding pads.

In the example of FIG. 1, the pads 108 are dimensioned to receive corresponding conductive elements that are implemented by any suitable conductor such as, for example, solder balls 112. In some examples, the solder balls 112 are placed into the pads 108 by changing their phase from solid to liquid via any suitable process (e.g., a screen printing process, etc.). In some examples, a solder paste is deposited into the pads 108 and transform into a liquid solder upon reaching a transition temperature.

When placed into the pads 108, the liquid solder 112 has a surface tension that causes a thin layer at a surface of a liquid solder 112 to behave as an elastic layer. Generally, molecules within a liquid (i.e., the molecules within the bulk of the liquid) are pulled in equal and opposite directions by intermolecular forces of neighboring molecules (i.e., Van der Waals forces). Because, molecules at a surface of the liquid neighbor molecules of a neighboring medium (e.g., air), the molecules at the surface of the liquid are pulled inwardly by the intermolecular forces of the bulk of the liquid, thereby creating the noted surface tension.

In the example of FIG. 1, the liquid solder 112 is forced into the radially shaped pads 108 via an external force (e.g., gravity, etc.). The liquid solder 112 includes a first surface 116 that contacts the pads 108 and a second surface 118 that does not contact the pads 108. When the liquid solder 112 is placed into the pads 108, the liquid solder 112 fills the pads 108, thereby causing the first surface 116 of the liquid solder 112 to have a radially shaped profile.

The surface tension causes the second surface 118 to be radially shaped. Thus, the second surface 118 of the liquid solder 112 is configured to have a radially shaped profile. After placing the liquid solder 112 in the pads 108, the liquid solder 112 cools and solidifies to form the solder balls 112. In the illustrated example, the solder balls 112 have an oblate spheroid shape.

In the illustrated example, the first surface 116 of each solder ball 112 has a major axis having a first distance 120 and a minor axis having a second distance 122. The first distance 120 is larger than the second distance 122. The second surface 118 also has a major axis having a third distance 124 and a minor axis having a fourth distance 126. The third distance 124 is larger than the fourth distance 126. In the illustrated example, the first distance 120 and the third distance 124 may or may not be substantially equal and the second distance 122 and the fourth distance 126 are substantially equal.

In the illustrated example, one or more holes 128 are formed in the substrate 102 by any suitable process (e.g., drilling, etching, etc.). Corresponding vias 130 are formed in each of the holes 128 by any suitable electrical conductor (e.g., copper plating, aluminum slug, etc.). In the illustrated example, the vias 130 electrically couple the solder balls 112 to one or more devices (e.g., an integrated circuit, etc.) at the active surface 132 of the substrate 102.

FIG. 2 illustrates the example substrate 102 in an inverted position relative to FIG. 1 and attached to another layer 202 (e.g., an interdisposing layer in a stacked integrated circuit configuration, an integrated circuit, a circuit board, etc.) via the solder balls 112. The layer 202 of the illustrated example includes one or more electrically conductive pads 204 (e.g., copper, etc.) to receive the solder balls 112. The solder balls 112 are attached to the pads 204 via any suitable process (e.g., solder reflow, etc.). In some examples, the solder balls 112 electrically couple devices associated with the substrate 102 (e.g., an integrated circuit attached to the active surface 132 of the substrate 102, etc.) to devices associated with the layer 202 (e.g., a packaged integrated circuit, etc.).

In an example solder reflow process, the substrate 102 is placed on the layer 202 such that the solder balls 112 are in contact with the pads 204. The solder balls 112 are heated to change the phase of at least a portion of the solder from solid to liquid. The solder is then cooled, thereby causing the solder 112 to electrically and mechanically couple the pads 108 to the pads 204. During this process, an external force applied to the substrate 102 (e.g., gravity) causes the substrate 102 to move toward the layer 202, thereby causing the liquid solder 112 to compress. As a result, a distance from the inactive surface 104 to the layer 202 decreases and the shape of the liquid solder 112 changes under the influence of the external force.

In the illustrated example, the radial profile of the first surface 116 of the liquid solder 112 does not substantially change because the radially shaped pad 108 provides a constant molding surface. However, the radially shaped profile of the second surface 118 changes in response to the external force. In particular, the fourth distance 126 decreases as the distance between the inactive surface 104 of the substrate 102 and the layer 202 decreases. The volume of the liquid solder 112 does not substantially change. As a result, the third distance 124 increases in response to decreasing the fourth distance 126. Thus, the external force causes the second surface 118 to expand its surface area.

In the example of FIG. 2, the first surface 116 of the solder ball 112 is configured to have a first radial shape and the second surface 118 is configured to have a second radial shape different from the first shape. As a result, joints 206 and 208 exist where the surfaces 116, 118 interface at the first surface 104 of the substrate 102. However, the liquid solder 112 remains substantially centered in the pads 108. In addition, an angle exists between the surfaces 116, 118 at the joints 206, 208. In particular, the second surface 118 of the liquid solder 112 absorbs increasing amounts of energy as the angle between the surfaces 116, 118 increases, thereby limiting the third distance 124 of the second surface 118. By limiting the third distance 124 of the second surface 118, the joints 206, 208 thereby prevent the shape of the second surface 118 from changing such that the liquid solder 112 contact each other and, thus, preventing electrical shorts when attaching the substrate 102 to the layer 202.

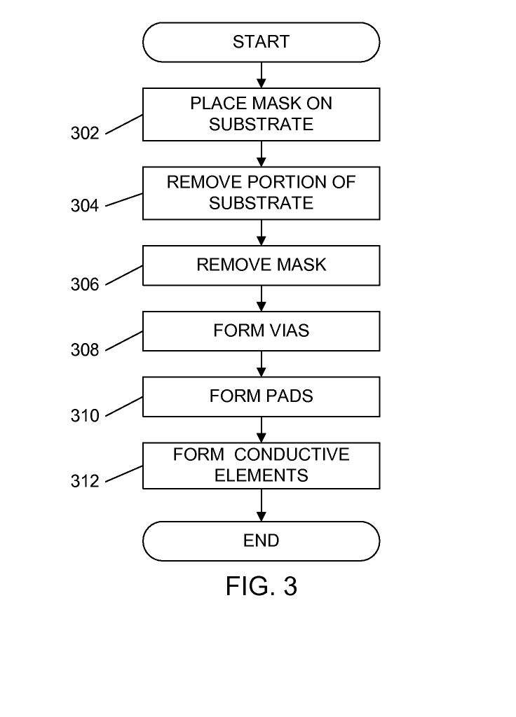

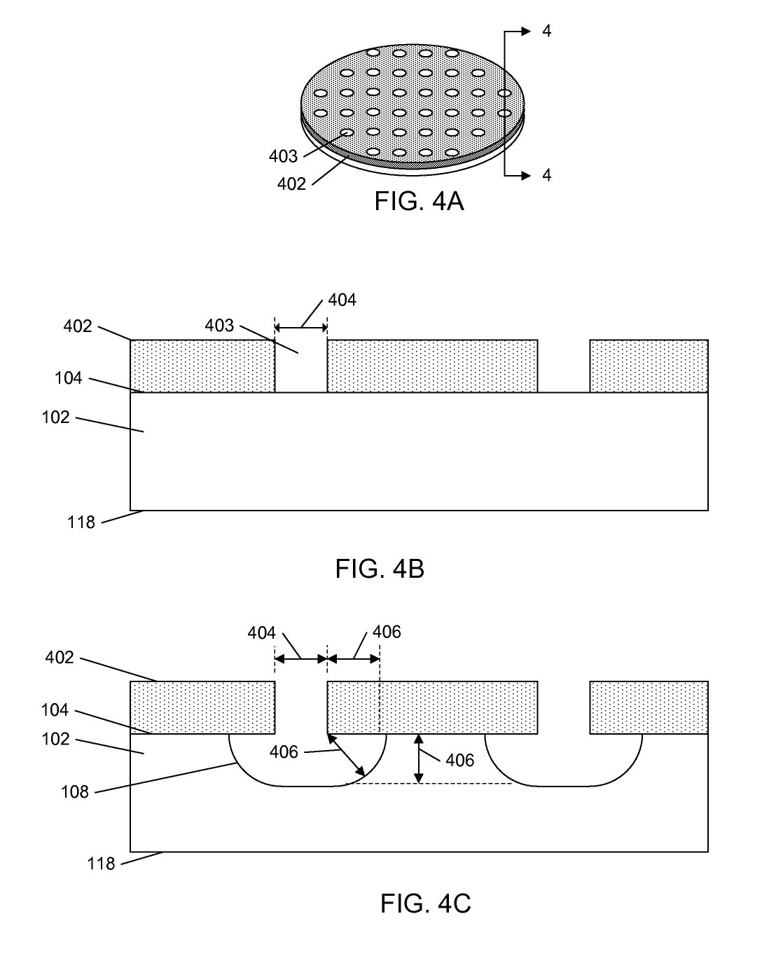

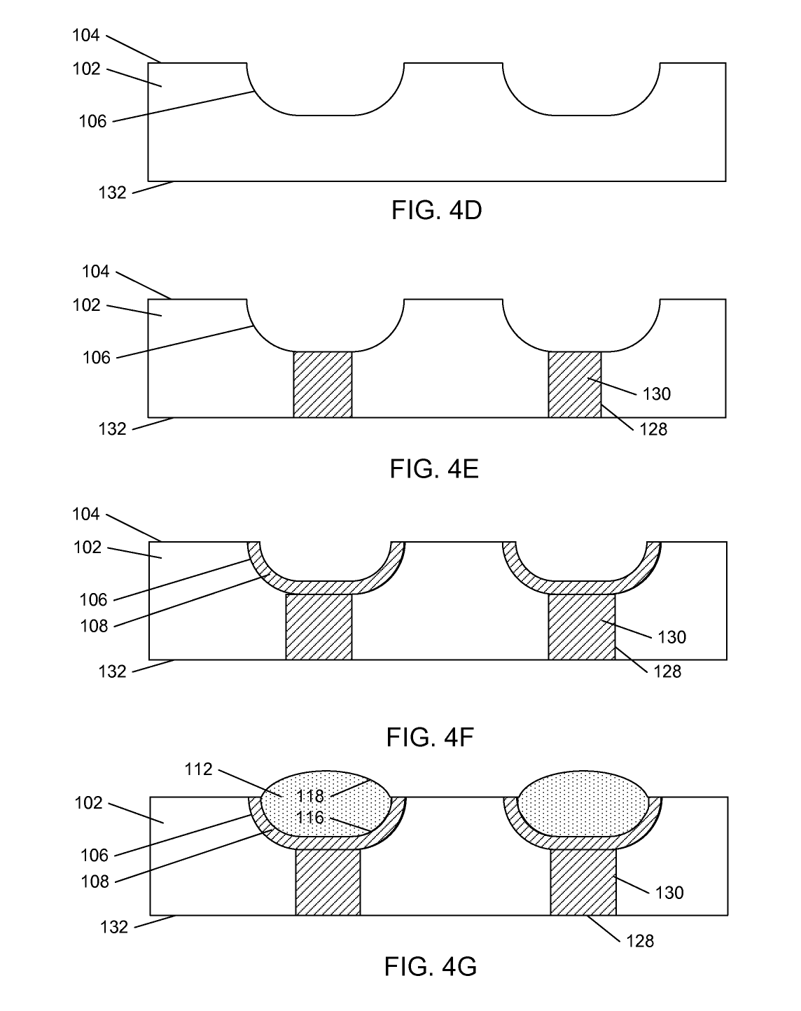

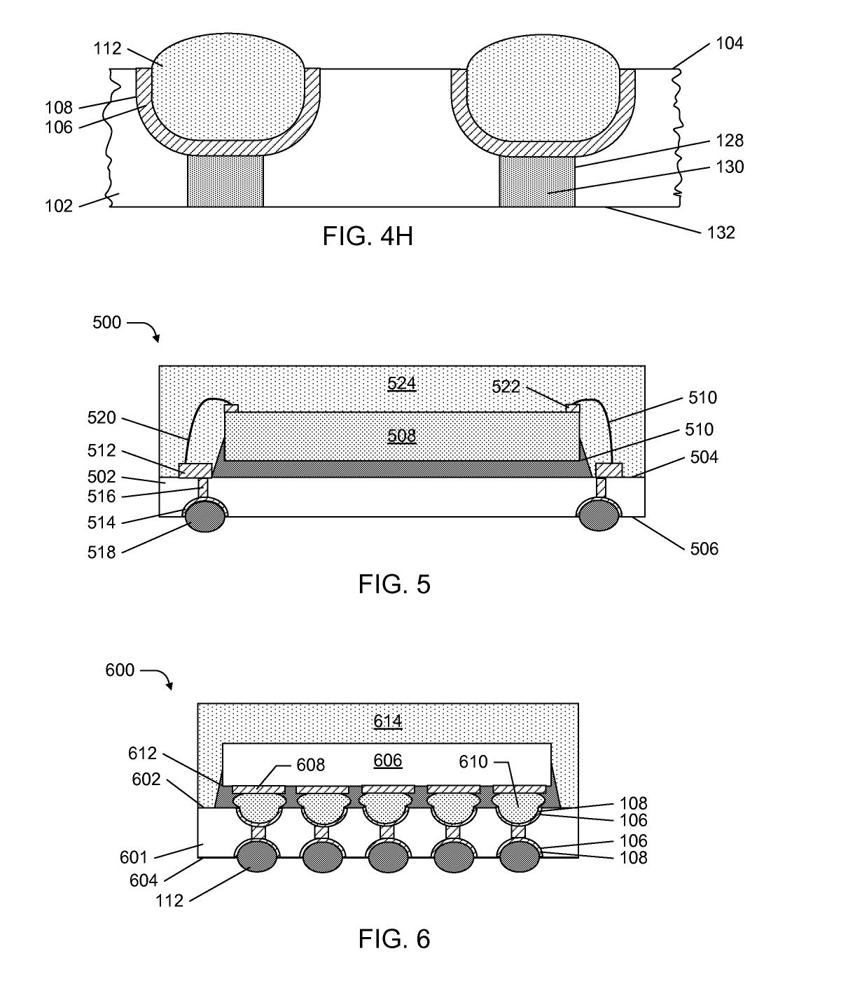

FIG. 3 illustrates an example process 300 to form the radially shaped pads 108 in the substrate 102 of FIG. 1. The example process 300 will be explained in conjunction with FIGS. 4A-4G, which illustrate the example substrate 102 at different stages of the example process 300. The example process 300 may be applied at any stage of a semiconductor manufacturing process (e.g., before the integrated circuit is attached to the substrate, after a mold is formed over the substrate, etc.).

In the example of FIG. 4A, the example process 300 begins by applying a mask 402 to the first surface 104 of the substrate 102 (block 302). In the illustrated example, the mask 402 is configured to leave one or more regions of the substrate 102 exposed. The exposed area(s) may have any desired shape(s). In the illustrated example, the exposed areas all have the same shape of a circle 403. FIGS. 4B-4G illustrates a cross section of the substrate 102 taken at lines 4-4. In the example of FIG. 4B, the mask 402 exposes the circle 403, which is represented by a distance (i.e., diameter) 404. The mask 402 may be implemented with any suitable material (e.g., silicon nitride (Si₃N₄), silicon dioxide (SiO₂), gold (Au), etc.).

After applying the mask 402, as illustrated in the example of FIG. 4C, a portion of the substrate 102 is selectively removed via any suitable process (e.g, wet etching, etc.) (block 304). In the illustrated example, an isotropic etching process selectively removes portions of the substrate 102 based on the shape of the mask 402. A suitable etching material (e.g., a buffered hydrochloric acid, a hydrofluoric acetic acid solution (e.g., HF+HNO₃+CH₃COOH), etc.) is selected to remove the portions of the substrate 102 that are exposed by the mask 402. Generally, the amount of substrate 102 removed by the etching material is based on the time that the etching material is applied to the substrate 102 and the size of the opening 403 in the mask 402. In the illustrated example, the substrate 102 is implemented by silicon and an example etching material removes 1 micron of silicon per minute. Thus, after 20 minutes, a depth of 20 microns of silicon is removed from the substrate 102. However, because the etching process is isotropic, the etching material removes substrate 102 at the same rate in all directions. Thus, as illustrated in the example of FIG. 4C, the etching material removes the substrate 102 in a radial direction to form the recesses 106 in the substrate 102.

Because the recesses 106 are formed based on the isotropic etching process and the mask 402, the parameters of the example process 300 (e.g., etching time, the distance 404, etc.) determine the shape of the recesses 106. In the illustrated example, the recesses 106 of FIG. 4C may be approximated by an elliptically shaped profile (e.g., a dimple) that is described in Cartesian coordinates by equation 1 below.

$$\frac{{x}^{2}}{{A}^{2}} + \frac{{y}^{2}}{{B}^{2}} = 1 \qquad [ Equation 1 ]$$

where A is the length of the major axis and B is the length of the minor axis. The major axis is the diameter of the recess and the minor axis the depth of the recess at its center. The length of the major axis is based on half of a total width of the recesses 106 and is described by equation 2 below.

A=0.5D₄₀₄+R₄₀₆ [Equation 2]

where D₄₀₄ is the distance 404 exposed by the mask 402, and R₄₀₆ is the distance 406 that the etching material removes based on the etching time. In the illustrated example, the length of the minor axis is substantially equal to the distance 406. Thus, based on the parameters of the etch process, the profile of each recess 106 is described by equation 3 below.

$$\frac{{x}^{2}}{{( 0.5 {D}_{404} + {R}_{406} )}^{2}} + \frac{{y}^{2}}{{R}_{406}^{2}} = 1 \qquad [ Equation 3 ]$$

where D₄₀₄ is the distance 404 and R₄₀₆ is the distance 406.

As described above, the parameters of the example process 300 (e.g, etch time, mask configuration, etching material, substrate material, etc.) control the shape of the recesses 106 and, thus, the parameters may be adjusted to achieve the desired radially shaped pads 108. For example, because the exposed gap in the mask 402 is a circle 403, the recesses 106 may be approximated by an oblate spheroid (i.e., an ellipse rotated about its minor axis) and, thus, its volume may be calculated based on the parameters of the etching process 300. In other words, the recesses 106 have a three-dimensionally, radial shape based on the parameters of the example process 300.

After the desired recesses 106 are formed in the substrate 102, the mask 402 is removed by any suitable process (e.g., a strip, etc.) as shown in the example of FIG. 4D (block 306). In some examples, vias 130 are placed in the substrate 102 (block 308). In the example of FIG. 4E, a hole 128 is formed in the substrate 102 using any suitable process (e.g., etching, etc.) then a via 130 is formed in the hole 128 (block 310). In the example of FIG. 4F, the pads 108 are formed in the recesses 108 via under bump metallization (block 310) and are in contact with the vias 130.

As illustrated in the example of FIG. 4G, conductive elements such as solder balls 112 are formed on the pads 108 by, for example, depositing liquid solder or solder paste (block 312). As described above, due to the surface tension of the liquid solder, the resulting solder balls 112 have radially shaped profiles. In the example of FIG. 4G, the solder balls 112 have oblate spheroid shapes.

The example process 300 of FIG. 3 ends after the solder balls 112 are formed in the pads 108. Although the foregoing describes a particular sequence of operations, the sequence of operations of the example process 300 may vary. For example, the stages of the process may be rearranged, combined, or divided. In some examples, stages of the process may be removed. Alternatively or additionally, some or all of the materials described above may be changed.

Alternatively or additionally, additional stages, processes or operations may be added. For example, the example process 300 may include an anisotropic etching to further configure the shape of the pads by, for example, making the recesses 106 deeper in the substrate 102. FIG. 4H illustrates such example recesses 106 and their corresponding pads 108. In such examples, the anisotropic etching process is configured to remove portions of the substrate 102 perpendicular to the first surface 104 of the substrate 102. After the anisotropic etching process, the isotropic etching process is configured based on the desired shape of the recess, thereby allowing more control over the final shape of the recesses 106.

Additionally, the example process 300 of FIG. 3 may occur at any desired stage of a process to manufacture a packaged integrated circuit. In some examples, the substrate 102 does not contain any active devices and the recesses 106 and pads 108 are formed before an integrated circuit is attached to the substrate 102. In such examples, the solder balls 112 are formed after an integrated circuit is sealed by an encapsulant (e.g., a molding compound, etc.). Still, in other examples, the substrate 102 may be an integrated circuit in a stacked integrated circuit configuration in which two or more integrated circuits are positioned over each other and through-silicon vias route electrical signals between the integrated circuits. In such an example, the example process 300 occurs before the integrated circuits are sealed by an encapsulant.

A substrate 102 incorporating the radially shaped pads 108 of FIG. 1 may be used in any number of configurations. FIG. 5 illustrates an example packaged integrated circuit 500 incorporating an example substrate 502 (e.g., a silicon interposer) that does not have any active devices on either its first surface 504 or its second surface 506. In the illustrated example, an integrated circuit 508 is attached to the first surface 504 of the substrate 502 via an adhesive 510 (e.g., epoxy, etc.). The first surface 504 of the substrate 502 includes one or more pads 512 that are electrically coupled to one or more radially shaped pads 514 on the second surface 506 of the substrate 502 by corresponding vias 516. The pads 514 have corresponding conductive elements such as solder balls 518 (e.g., micro solder bumps), for example.

In the illustrated example, one or more bond wires 520 electrically couple the pads 512 to corresponding contacts 522 of the integrated circuit 508. An encapsulant 524 (e.g., a resin mold, etc.) seals the integrated circuit 508 and its associated components (e.g., the bond wires 520) to protect the same from the environment. In the example of FIG. 5, the radially shaped pads 514 allow the solder balls 518 to be placed closer in proximity to each other while preventing the solder balls 518 from shorting when being attached to a circuit board.

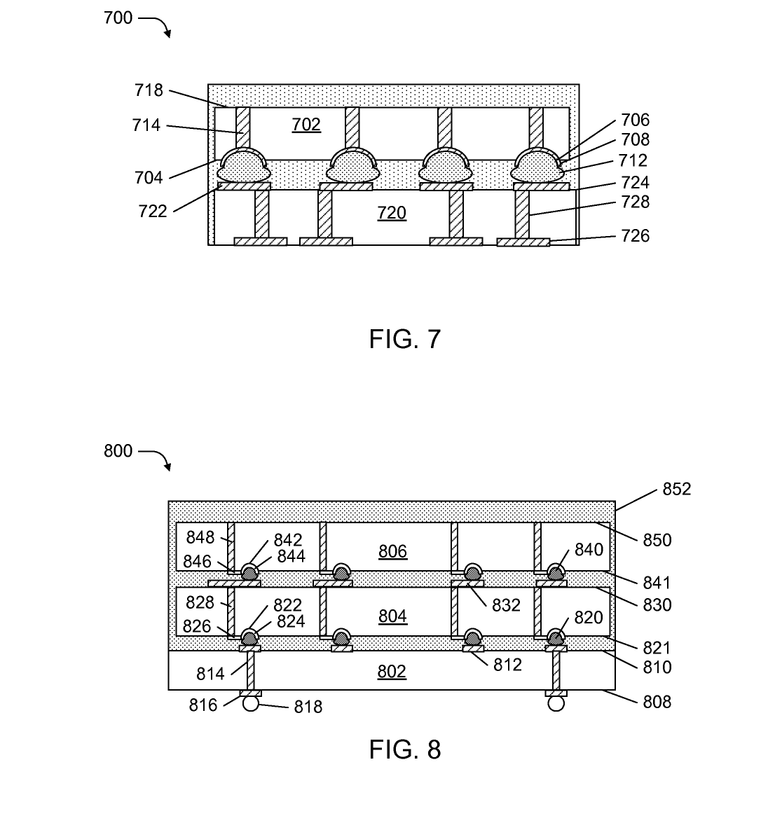

FIG. 6 illustrates another packaged integrated circuit 600 incorporating a substrate 601 having radially shaped pads. In the example of FIG. 6, the substrate 601 includes radially shaped pads 108 on both a first surface 602 and a second surface 604. In the illustrated example, the substrate 601 is configured to receive a flip-chip integrated circuit 606 having one or more contacts 608 and electrically couple the integrated circuit 606 to one or more conductive elements 610 disposed on the second surface 604. In the illustrated example, the substrate 601 and the integrated circuit 606 thereon are implemented by substantially the same material to have substantially equal thermal expansion coefficients. That is, the substrate 601 does not include any active devices and is configured to facilitate electrical and mechanical attachment of the integrated circuit 606 by forming a ball grid array, for example.

In the illustrated example, the integrated circuit 606 is attached to corresponding pads 108 on the first surface 602 of the substrate 601 via one or more conductive elements 610 (e.g., gold bumps, studs, solder balls, etc.), which are electrically coupled to the pads 108 on the second surface 604 of the substrate 601. An underfill 612 is placed between the first surface 602 of the substrate 601 and the flip-chip integrated circuit 606 to protect the conductive elements 610 from damage (e.g., from thermal stress, humidity, etc.). An encapsulant 614 seals the integrated circuit 606 and its associated components (e.g., the conductive elements 610, etc.) to protect the same from the environment. The radially shaped pads 108 are formed on the second surface 604 of the substrate 601 in substantially the same manner as pads 108 are formed on the first surface 602 of the substrate 601.

In some examples, the radially shaped pads may be implemented in an integrated circuit that is attached to a package (e.g, a lead frame, a substrate, etc.). FIG. 7 illustrates such an example packaged integrated circuit 700 including an integrated circuit 702. A surface 704 of the integrated circuit 702, which, in this example, is the non-circuit surface, defines one or more radially shaped recesses 706 and includes one or more pads 708 formed in the recesses 706 to receive one or more solder balls 712. In the illustrated example, the pads 708 are in contact with the vias 716, thereby not requiring routing pads (i.e., traces) on the surface 704. The vias 716 further couple devices on a surface 718 of the integrated circuit 702 to the solder balls 712 located on the surface 704.

In the illustrated example, the integrated circuit 702 is attached to a substrate 720 via, for example, the solder balls 712. The solder balls 712 are received by corresponding pads 722 on a surface 724 of the substrate 720. The pads 722 are electrically coupled to one or more contacts 726 of the packaged integrated circuit 700 through one or more vias 728. An encapsulant 730 seals the contents of the packaged integrated circuit 700 to protect the same while leaving the contacts 726 exposed on one or more surfaces of the packaged integrated circuit.

In addition, the radially shaped pads may be implemented in, for example, a stacked integrated circuit (e.g., a multi-layered circuit including two or more integrated circuits stacked and in communication with each other). FIG. 8 illustrates an example two-layer packaged integrated circuit 800 having a substrate 802 with first and second integrated circuits 802 and 804 attached thereto. In the example two-layered packaged integrated circuit 800, integrated circuits are stacked and implement through-silicon vias to route signals to and from the integrated circuits.

In particular, the substrate 802 includes a first surface 808 and a second surface 810 opposite the first surface. The second surface 810 includes one or more pads 812 to receive the integrated circuit 804. The pads 812 are electrically coupled to one or more vias 814 that are in contact with one or more pads 816 on the first surface 808. One or more conductive elements such as solder balls 818 (e.g., micro solder bumps) are placed on pads 816 to interface with, for example, a circuit board.

The first integrated circuit 804 is attached to the pads 812 of the substrate 802 via one or more conductive elements such as solder balls 820 on a first surface 821 of the integrated circuit 804. In the illustrated example, the integrated circuit 804 includes one or more recesses 822 having radially shaped pads 824. The solder balls 820 are disposed in the radial shaped pads 824 to, for example, substantially fix the location of the solder balls 820. The pads 824 are in contact with one or more routing traces 826 which are in further contact with one or more through-chip vias 828. The through-chip vias 828 electrically couple the solder balls 820 with active devices (e.g., transistors, circuits, etc.) located on a second surface 830 of the integrated circuit 804.

In the illustrated example, the second surface 830 of the integrated circuit 804 includes one or more pads 832 to receive the second integrated circuit 806. The second integrated circuit 806 includes one or more conductive elements such as solder balls 840 disposed on a first surface 841 of the second integrated circuit 806. In particular, the first surface 841 defines one or more recesses 842 that have radially shaped pads 844. The solder balls 840 are disposed in the radial shaped pads 844 to, for example, substantially fix the location of the solder balls 840. The pads 844 are in contact with one or more routing traces 826, which are in further contact with one or more through-chip vias 848. The through-chip vias 848 electrically couple the solder balls 840 with active devices on a second surface 850 of the integrated circuit 806. The integrated circuits 804, 806 are sealed by an encapsulant 852 to protect its contents from the environment.

The through-chip vias 828, 848 route electrical signals to and from the integrated circuits 804, 806 of the multi-layer circuit. In such examples, the through-chip vias 828, 848 are placed throughout the packaged integrated circuit 800. By implementing such vias 828, 848, multiple integrated circuits may be contained within the packaged integrated circuit 800. In the illustrated example, stacking the integrated circuits reduces the size of the footprint required on a circuit board. Reducing the trace length between the integrated circuits by stacking the same may also improve the performance of the packaged integrated circuit 800 relative to a system in which the integrated circuits 804, 806 are placed side by side on a circuit board.

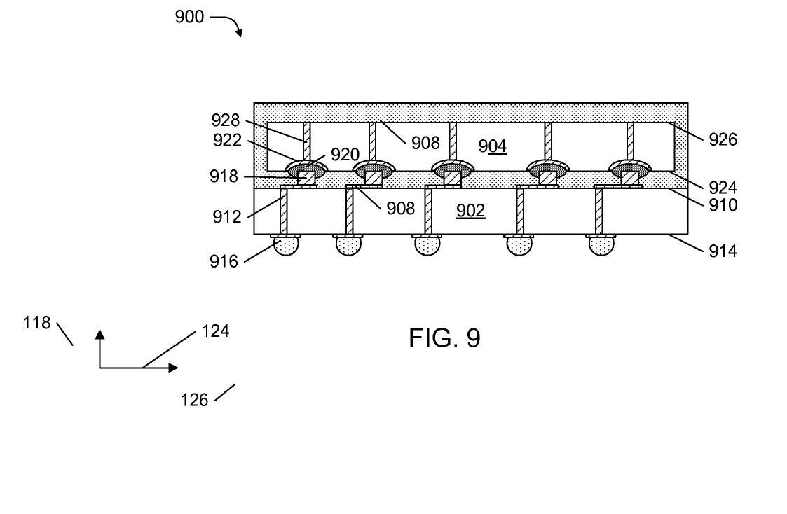

In addition, the radially shaped pads may be implemented to achieve finer pitch for conductive elements such as solder balls, for example. FIG. 9 illustrates a two layer packaged integrated circuit 900 implementing posts (e.g., stud bumps) to finely control the pitch of such solder balls. In the illustrated example, a substrate 902 is configured to receive an integrated circuit 904. In particular, the substrate 902 includes one or more pads 908 on a first surface 910 to receive the integrated circuit 904. The pads 908 are coupled to corresponding vias 912 that electrically couple the pads 908 to a second surface 914 opposite the first surface. In particular, the vias 912 couple the pads 908 to one or more conductive elements such as solder balls 916, for example. Further, the pads 908 also include studs 918 (e.g., stud bumps, posts, etc.) to receive a corresponding integrated circuit.

The first integrated circuit 904 is coupled to the stud bumps 918 via conductive elements such as, for example, solder balls 920 placed in one or more recessed pads 922 on a first surface 924 of the integrated circuit 904. A second surface 926 opposite the first surface 924 includes active devices therein and may be coupled to the substrate 902 by vias 928 through the integrated circuit 904. In the illustrated example, the radially shaped pads 922 are in direct contact with the vias 928, thereby not requiring routing layers (i.e., traces) to be placed on the first surface 924. In such an example, the via 928 may be formed before forming the radially shaped pads 928.

In such examples, the solder balls 920 are implemented by a solder paste to electrically and mechanically couple the studs 918 to the pads 922 during solder reflow. In particular, the radial shape of the pads 922 improve the placement of solder paste, for example. As a result, the pads 922 improve manufacturability of the packaged integrated circuit 900 and a finer pitch between the solder balls 920 can be achieved.

The above described approaches provide methods to form pads on substrates such as integrated circuits and so forth. In the described examples, radially shaped pads are formed to allow conductive elements (e.g., solder balls) to be placed therein. As a result of the radially shaped pads, the position of the conductive elements is substantially fixed in the center of the radially shaped pads, thereby improving manufacturability of integrated circuits. The radially shaped pads also cause the conductive elements to have a radial shape when formed in the pad. As a result, when such an integrated circuit is attached to another device (e.g., a circuit board), the pads control the shape of the conductive elements and significantly reduce the risk of electrical shorts due to solder reflow. Thus, the radially shaped pads also increase the reliability of manufacturing electronic devices. In some examples, the pads may also be placed closer together in proximity to provide a package having contacts with a higher density. The inclusion of such pads into existing fabrication processes is an inexpensive process change.

Although certain methods, apparatus, and articles of manufacture have been described herein, the scope of coverage of this patent is not limited thereto. On the contrary, this patent covers all apparatus, methods and articles of manufacture fairly falling within the scope of the appended claims either literally or under the doctrine of equivalents.

1. A method of forming a bonding pad in a packaged integrated circuit, comprising:
isotropically etching a portion of a surface of a substrate to form a recess having a radial shape;
forming a conductive layer in the recess to form the bonding pad; and
placing a conductive element in the pad.

2. A method as defined in claim 1, wherein the conductive element has a radial shape based on the recess.

3. A method as defined in claim 2, wherein the conductive element comprises a solder ball.

4. A method as defined in claim 1, wherein isotropically etching a portion of the substrate comprises:
placing a mask on a non-circuit surface of the substrate, the mask exposing a portion of the non-circuit surface; and
applying an etching material to the exposed portion to selectively remove the exposed portion of the substrate.

5. A method as defined in claim 4, wherein the radial shape of the recess is based on a shape exposed by the mask and an etch time.

6. A method as defined in claim 1, wherein the conductive element is substantially centered in the pad.

7. A method as defined in claim 1, further comprising selectively encapsulating the substrate with an encapsulant with the conductive element exposed for contact.

8. A method as defined in claim 1, wherein the shape of the recess is based on one or more parameters of the substrate and an isotropic characteristic of an etching material.

9. A method as defined in claim 9, wherein the parameters comprise a material of the substrate and a time the substrate is exposed to the etchant.

10. A method as defined in claim 1, further comprising anisotropically etching a portion of a surface of a substrate.

11. A packaged integrated circuit, comprising:
an integrated circuit attached to a first surface of a substrate, the substrate defining a recess having a three-dimensionally curved, radial shape on a second surface opposite the first surface;
a conductive pad in the recess having a radial shape corresponding to the recess; and
a conductive element in the recess, the conductive element being electrically coupled to the integrated circuit by a via through the substrate.

12. A packaged integrated circuit as defined in claim 11, wherein the conductive element is a solder ball.

13. A packaged integrated circuit as defined in claim 11, wherein the conductive element is substantially centered in the pad.

14. A packaged integrated circuit as defined in claim 11, wherein the substrate has an isotropic etching characteristic.

15. An integrated circuit as defined in claim 11, further comprising an encapsulant to encapsulate the integrated circuit with the conductive element exposed.

16. A packaged integrated circuit, comprising:
a first substrate having one or more active devices on a first surface, the first substrate defining one or more recesses having a three-dimensionally curved, radial shape on a second surface opposite the first surface and conductive pads in the recesses having a radial shape corresponding to the recesses, conductive elements located in corresponding ones of the recesses;
a second substrate having a first surface to receive the conductive elements of the first substrate and a second surface opposite the first surface having one or more contacts electrically coupled to the active devices of the first substrate; and
an encapsulant to encapsulate the first and second substrates, wherein the contacts of the second substrate are exposed on one or more surfaces of the packaged integrated circuit.

17. A packaged integrated circuit as defined in claim 16, wherein the conductive elements are solder balls.

18. A packaged integrated circuit as defined in claim 16, wherein the conductive elements are substantially centered in the pads.

19. A packaged integrated circuit as defined in claim 16, wherein the first substrate has an isotropic etching characteristic.

20. A packaged integrated circuit as defined in claim 19, wherein the shape of the recesses is based on one or more parameters of the isotropic etch process.

21. A packaged integrated circuit as defined in claim 20, wherein the parameters comprise an amount of the substrate to be removed and a time an etchant is applied to the substrate.

22. A packaged integrated circuit as defined in claim 16, further comprising a third substrate having one or more active devices on a first surface, the first substrate defining one or more recesses having a three-dimensionally curved, radial shape on a second surface opposite the first surface and conductive pads in the recesses having a radial shape corresponding the recesses, and conductive elements located in the recesses and being coupled to one or more pads on the first substrate.

23. A packaged integrated circuit as defined in claim 16, the first substrate defining one or more vias to couple the active devices to corresponding routing traces on the second surface of the first substrate, the routing traces being in circuit with the pads.

24. A packaged integrated circuit as defined in claim 16, the first substrate defining one or more vias through the first substrate to couple the active devices to corresponding routing traces on the second surface of the first substrate, the vias being in circuit with the pads.

25. A packaged integrated circuit as defined in claim 16, the second substrate having one or more stud bumps on the first surface to receive corresponding conductive elements of the first substrate.
